(19) United States
(12) Patent Application Publication
(10) Pub. No.: US 2014/0225633 A1
(43) Pub. Date: Aug. 14, 2014

(54) FIXTURE, SYSTEM AND METHOD FOR PERFORMING FUNCTIONAL TEST

(71) Applicant: TEST RESEARCH, INC., Taipei City (TW)

(72) Inventors: Su-Wei TSAI, Taiwan (TW); Wei-Ren WANG, Taiwan (TW)

(73) Assignee: TEST RESEARCH, INC., Taipei City (TW)

(21) Appl. No.: 13/875,101

(22) Filed: May 1, 2013

(30) Foreign Application Priority Data
Jan. 17, 2013 (TW) 102101785

(51) Int. Cl. G01R 31/319

(52) U.S. Cl. CPC G01R 31/31917
USPC 324/750.01

(57) ABSTRACT

A fixture for performing functional test is provided. The fixture comprises an interface module and a test control module. The interface module is connected to an under-test module. The test control module controls the interface module to communicate with a self-test unit of the under-test module to activate a test flow and to determine whether the under-test module is under a passive test mode or an active test mode. When the under-test module is under the passive test mode, the test control module transmits at least one test command to the self-test unit to perform tests. When the under-test module is under the active test mode, the test control module receives a control command and/or a test result from the self-test unit passively to perform tests on the under-test module by controlling the interface module according to the control command and/or analyze the test result.

### RELATED APPLICATIONS

This application claims priority to Taiwan Application Serial Number 102101785, filed Jan. 17, 2013, which is herein incorporated by reference.

### BACKGROUND

1. Technical Field

The present invention relates to a test technology. More particularly, the present invention relates to a fixture, a system and a method for performing functional test.

2. Description of Related Art

Test technology is important in the manufacturing process of the electronic products. It is impossible to accomplish 100% yield rate in the manufacturing process of the chips. Accordingly, it is necessary to perform a test procedure on the chips to determine whether the functions of the chips are normal before the chips proceed to the packaging process. The test procedure focuses on the structure and the function of the chips. The tests related to the structure of the chips may be used to determine whether the electrical connection of the pins or other physical connection interface is normal. The tests related to the function of the chips may be used to determine whether the functions performed by the chips and the related circuit, or the inputted or the outputted signals are correct.

In conventional design, the functional test is performed by delivering commands from a computer host to the test equipment and transmitting the related signals or commands to the under-test module through the corresponding fixture such that the under-test module can operate according to the command. The test result is transmitted back to the computer host through the fixture and the test equipment such that the computer host can analyze the test result. However, the size of the computer host and the test equipment is large and is not convenient for the user to operate. Further, most of the chips have the ability to perform self-test. There are large parts of the test procedure that do not have to rely on the computer host and the test equipment. If the conventional test system is used to perform tests on the chips equipped with self-test mechanism, there would be some unnecessary cost since some of the functions are overlapped between the chips and the conventional test system.

Accordingly, what is needed is a fixture, a system and a method for performing functional test to lower the size of the test system and increase the efficiency of the test flow in cooperation with the chips having the self-test mechanism.

### SUMMARY

An aspect of the present invention is to provide a fixture for performing functional test. The fixture comprises an interface module and a test control module. The interface module is connected to an under-test module. The test control module controls the interface module to communicate with a self-test unit of the under-test module to activate a test flow and to determine whether the under-test module is under a passive test mode or an active test mode. When the under-test module is under the passive test mode, the test control module transmits at least one test command to the self-test unit to perform tests. When the under-test module is under the active test mode, the test control module receives a control command and/or a test result passively from the self-test unit to perform the tests on the under-test module by controlling the interface module according to the control command and/or analyze the test result.

Another aspect of the present invention is to provide a functional test system. The functional test system comprises an under-test module and a fixture. The under-test module comprises a self-test unit. The fixture comprises an interface module and a test control module. The interface module is connected to the under-test module. The test control module controls the interface module to communicate with the self-test unit of the under-test module to activate a test flow and to determine whether the under-test module is under a passive test mode or an active test mode. When the under-test module is under the passive test mode, the test control module transmits at least one test command to the self-test unit to perform tests. When the under-test module is under the active test mode, the test control module receives a control command and/or a test result passively from the self-test unit to perform the tests on the under-test module by controlling the interface module according to the control command and/or analyze the test result.

Yet another aspect of the present invention is to provide a functional test method used in a fixture. The functional test method comprises the steps outlined below. A self-test unit of an under-test module is communicated with a test control module of the fixture through an interface module of the fixture to control the under-test module to activate a test flow. Whether the under-test module is under a passive test mode or an active test mode is determined. When the under-test module is under the passive test mode, the test control module transmits at least one test command to the self-test unit to perform tests. When the under-test module is under the active test mode, the test control module receives a control command and/or a test result passively from the self-test unit to perform the tests on the under-test module by controlling the interface module according to the control command and/or analyze the test result.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a block diagram of a functional test system of an embodiment of the present invention;

FIG. 2 is a block diagram of the functional test system in another embodiment of the present invention;

FIG. 3 is a flow chart of a functional test method of an embodiment of the present invention; and

FIG. 4 is a flow chart of a functional test method of another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

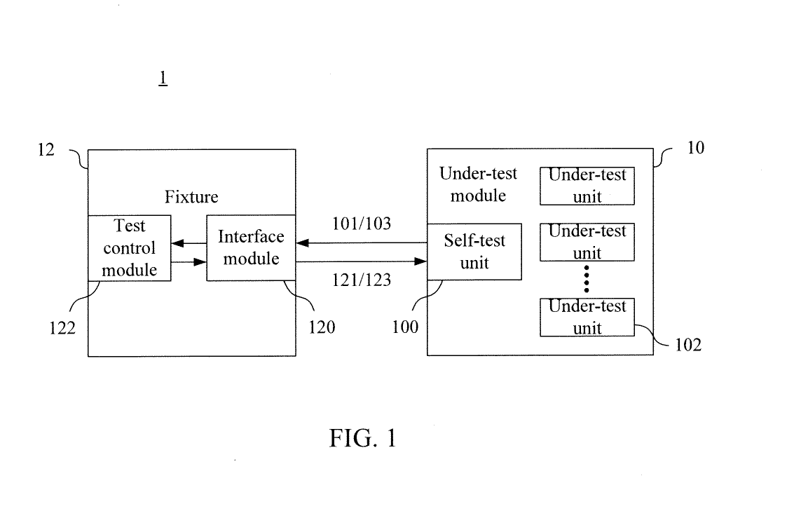

FIG. 1 is a block diagram of a functional test system 1 of an embodiment of the present invention. The functional test system 1 comprises an under-test module 10 and a fixture 12.

The under-test module 10 comprises a self-test unit 100 and a plurality of under-test units 102. In an embodiment, the self-test unit 100 may comprise a processing module (not shown) and a firmware programmed in an electrically-erasable programmable read-only memory (EEPROM) (or other memory devices such as a flash memory), such that multiple self-tests, such as the measurement of the currents and voltages or whether the signal transmission is normal, can be performed on the under-test module 10 itself according to the procedures programmed in the firmware. The under-test units 102 may perform different functions according to different designs of the under-test module 10. Hence, the under-test units 102 are the target of the functional test.

The fixture 12 comprises an interface module 120 and a test control module 122. The interface module 120 is connected to the under-test module 10. In an embodiment, the interface module 120 is a circuit module designed according to the under-test module and has transmission interfaces and auxiliary test circuits. The transmission interface may comprise such as, but not limited to, a universal asynchronous receiver transmitter (UART) interface, an I²C interface, a universal serial bus (USB) interface, a Bluetooth interface or a combination of the above. The test control module 122 and the self-test unit 100 of the under-test module 10 can communicate with each other to transmit commands and data. Further, the interface module 120 may further comprise other circuits connected to the under-test module 10 to aid the test procedure of the under-test module 10.

The test control module 122 controls the interface module 120 and, as described above, communicates with the self-test unit 100 of the under-test module 10 to activate the under-test 10 to further activate a test flow. In an embodiment, when the test flow initialized, the test control module 122 can control the under-test module 10 through the interface module 120 to provide power to the under-test module 10 and activate the under-test module 10.

The test control module 122 further determines whether the under-test module 10 is under a passive test mode or an active test mode. When the under-test module 10 is under the passive test mode, the test control module 122 serves as the host and the under-test module 10 serves as the client. The test control module 122 can thus actively perform measurement on the under-test module 10. On the contrary, when the under-test module 10 is under the active test mode, the under-test module 10 serves as the host and the test control module 122 serves as the client. The under-test module 10 can thus perform self-test or control the test control module 122 to aid the test procedure of the under-test module 10 by using the circuit of the interface module 120 of the fixture 12.

In an embodiment, the under-test module 10 is under the passive test mode when it is activated. The test control module 122 can transmit a test command 121 to the self-test unit 100 such that the self-test unit 100 activates the corresponding under-test units 102 to perform test. The self-test unit 100 can perform test according to the test command 121 and retrieve the measurement result.

When parts of the test procedures are finished under the control of the test control module 122, it can transmit an active test mode switching command 123 to the self-test unit 100 such that the under-test module 10 switches to the active test mode. When the under-test module 10 is under the active test mode, the self-test unit 100 directly activates the under-test units 102 of the under-test module 10 to perform measurement. The self-test unit 100 can perform test on the under-test units 102 according to its own testing mechanism. In an embodiment, the under-test units 102 can also perform test to each other to accomplish the self-test mechanism.

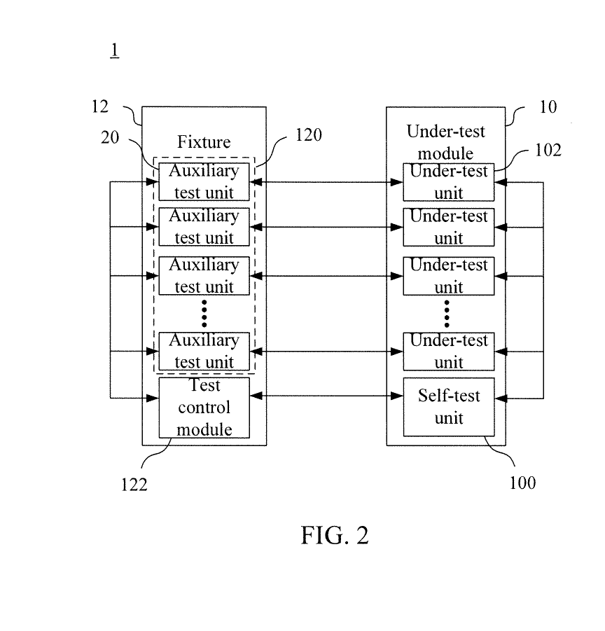

FIG. 2 is a block diagram of the functional test system 1 in another embodiment of the present invention. As shown in FIG. 2, the under-test module 10 comprises a self-test unit 100 and a plurality of under-test units 102. The fixture 12 comprises a test control module 122 and a plurality auxiliary test units 20 included in the interface module 120.

Under the active test mode, the under-test module 10 can transmit a control command 101 to the test control module 122 to use the fixture 12 to perform tests. The test control module 122 can control the circuit of the auxiliary test units 20 of the interface module 120 to aid the test procedure and transmit the measurement result back to the under-test module 10.

For example, if one of the under-test units 102 is an amplifier and the under-test module 10 is not equipped with a microphone, the under-test module 10 can transmit the control command 101 to the test control module 122 to use one of the auxiliary test units 20 on the fixture 12, e.g. a microphone, to receive the audio signal sent from the amplifier such that whether the playback result is correct can be determined.

On the other hand, the under-test module 10 can also transmit the test result to the test control module 122 under the active test mode such that the test control module 122 can analyze the test result.

In an embodiment, the under-test module 10 can transmit a passive test mode switching command 103 to the test control module 122 after parts of the test procedures are finished under the control of the under-test module 10 such that the test control module 122 serves as the host again to perform tests on the under-test module 10. For example, after the under-test module 10 finishes the functional test during the active mode, the functional test related to the sleep mode can be further performed. Hence, the under-test module 10 switches to the client to allow the fixture 12 serving as the host to perform tests on the under-test module 10 that is in the sleep mode.

Therefore, the fixture of the present invention can transmit test command through the test control module without the presence of the computer host and the test equipment. Hence, the size and the cost of the fixture can be lowered. The fixture and the under-test module having the self-test mechanism can serve as the host in turn to perform active and passive tests. The test procedure can thus be performed more elastically. Furthermore, it is more and more difficult to place test points on the under-test module for the fixture to perform measurement since the density of the circuit elements on the under-test module becomes higher and higher. Since the under-test module itself can perform parts of the test procedure, the number of the test points can be reduced.

When the under-test module is under the active test mode, the test control module receives a control command and/or a test result passively from the self-test unit passively to perform the tests on the under-test module by controlling the interface module according to the control command and/or analyze the test result.

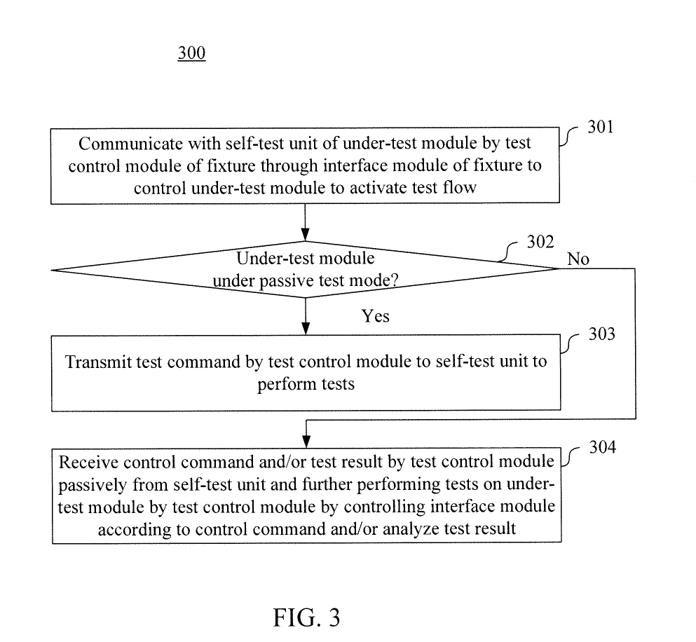

FIG. 3 is a flow chart of a functional test method 300 of an embodiment of the present invention. The functional test method 300 can be used in the fixture 12 of the functional test system 1 depicted in FIG. 1. The functional test method 300 comprises the steps outlined below (The steps are not recited in the sequence in which the steps are performed. That is, unless the sequence of the steps is expressly indicated, the sequence of the steps is interchangeable, and all or part of the steps may be simultaneously, partially simultaneously, or sequentially performed).

In step 301, the self-test unit 100 of the under-test module 10 is communicated with the test control module 122 of the fixture 12 through the interface module 120 of the fixture 12 to control the under-test module 10 to activate a test flow.

In step 302, whether the under-test module 10 is under the passive test mode or the active test mode is determined.

When the under-test module 10 is under the passive test mode, the test control module 122 transmits at least one test command 121 to the self-test unit 100 to perform tests in step 303.

When the under-test module 10 is under the active test mode, the test control module 122 receives the control command 101 and/or the test result passively from the self-test unit 100 in step 304 to perform the tests on the under-test module 10 by controlling the interface module 120 according to the control command 101 and/or analyze the test result.

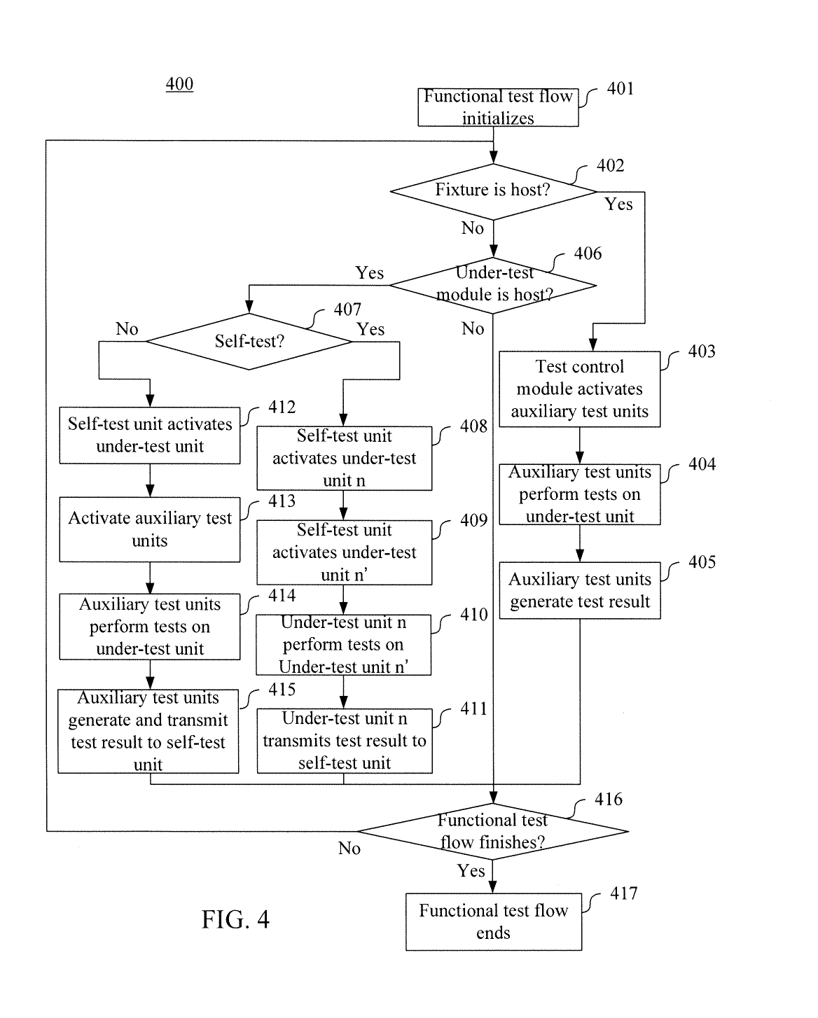

FIG. 4 is a flow chart of a functional test method 400 of another embodiment of the present invention. The functional test method 400 can be used in the fixture 12 of the functional test system 1 depicted in FIG. 1. The functional test method 400 comprises the steps outlined below (The steps are not recited in the sequence in which the steps are performed. That is, unless the sequence of the steps is expressly indicated, the sequence of the steps is interchangeable, and all or part of the steps may be simultaneously, partially simultaneously, or sequentially performed).

In step 401, the functional test flow initializes.

In step 402, whether the fixture 12 serves as the host is determined. When the fixture 12 is the host, the test control module 122 communicates with the self-test unit 100 to activate the under-test unit 102 in step 403.

In step 403, the test control module 122 activates the auxiliary test units 20 of the under-test units 102.

In step 404, the auxiliary test units perform tests on the under-test units 102.

In step 405, the auxiliary test units generate test result.

When the determining result shows that the fixture 12 is not the host, whether the under-test module 10 is the host is determined in step 406. When the under-test module 10 is the host, whether the test procedure is the self-test procedure performed independent of the fixture 12 is determined in step 407. When the test procedure is the self-test procedure, the self-test unit 100 activates the under-test unit n in step 408 and activates the under-test unit n′ in step 409. In step 410, the under-test unit n performs tests on the under-test unit n′. In step 411, the under-test n transmits the test result to the self-test unit 100.

When the test procedure is not the self-test procedure, the self-test unit 100 activates the under-test unit 20 in step 412. The self-test unit 100 communicates with the test control module 122 in step 413 to activate the auxiliary test unit 20 corresponding to the under-test unit 20. In step 414, the auxiliary test unit 20 performs tests on the under-test unit 20. In step 415, the auxiliary test unit 20 generates the test result and transmits the test result to the self-test unit 100.

When step 405, 411 and 415 are finished, or when the determining result shows that the under-test module 10 is not the host in step 406, the flow proceeds to step 416 to determine whether the test flow is finished. When the test flow is not finished yet, the flow goes back to step 401 to keep performing determination. When the test flow is finished, the functional test flow ends in step 417.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A fixture for performing functional test comprising:
an interface module connected to an under-test module; and
a test control module to control the interface module to communicate with a self-test unit of the under-test module to activate a test flow and to determine whether the under-test module is under a passive test mode or an active test mode;
wherein when the under-test module is under the passive test mode, the test control module transmits at least one test command to the self-test unit to perform tests;
when the under-test module is under the active test mode, the test control module receives a control command and/or a test result passively from the self-test unit to perform the tests on the under-test module by controlling the interface module according to the control command and/or analyze the test result.

2. The fixture of claim 1, wherein the under-test module is under the passive test mode when the test flow is initialized.

3. The fixture of claim 1, wherein when the under-test module is under the passive test mode, the test control module transmits an active test mode switching command such that the under-test module switches to the active test mode.

4. The fixture of claim 1, wherein when the under-test module is under the passive test mode, the self-test unit activates at least one under-test unit of the under-test module according to the test command and when the under-test module is under the active test mode, the self-test unit activates the under-test unit directly.

5. The fixture of claim 1, wherein when the under-test module is under the active test mode and when the test control module receives a passive test mode switching command from the self-test unit, the under-test module is determined to be switched to the passive test mode.

6. The fixture of claim 1, wherein the interface module further comprises a plurality of auxiliary test units such that after the test control module controls the auxiliary test units to perform test according to the test command when the under-test module is under the active test mode, the test control module further transmits a auxiliary measurement result to the self-test unit.

7. The fixture of claim 1, wherein the interface module further comprises an universal asynchronous receiver transmitter (UART) interface, an I²C interface, an universal serial bus (USB) interface, a Bluetooth interface or a combination of the above, and the test control module and the under-test module communicate with each other through the UART interface, the I²C interface, the USB interface, the Bluetooth interface or the combination of the above.

8. A functional test system comprising:
an under-test module comprising a self-test unit; and
a fixture comprising:
an interface module connected to the under-test module; and
a test control module to control the interface module to communicate with the self-test unit of the under-test module to activate a test flow and to determine whether the under-test module is under a passive test mode or an active test mode;
wherein when the under-test module is under the passive test mode, the test control module transmits at least one test command to the self-test unit to perform tests;
when the under-test module is under the active test mode, the test control module receives a control command and/or a test result passively from the self-test unit to perform the tests on the under-test module by controlling the interface module according to the control command and/or analyze the test result.

9. The functional test system of claim 8, wherein the under-test module is under the passive test mode when the test flow is initialized.

10. The functional test system of claim 8, wherein when the under-test module is under the passive test mode, the test control module transmits an active test mode switching command such that the under-test module switches to the active test mode.

11. The functional test system of claim 8, wherein when the under-test module is under the passive test mode, the self-test unit activates at least one under-test unit of the under-test module according to the test command and when the under-test module is under the active test mode, the self-test unit activates the under-test unit directly.

12. The functional test system of claim 8, wherein when the under-test module is under the active test mode and when the test control module receives a passive test mode switching command from the self-test unit, the under-test module is determined to be switched to the passive test mode.

13. The functional test system of claim 8, wherein the interface module further comprises a plurality of auxiliary test units such that after the test control module controls the auxiliary test units to perform test according to the test command when the under-test module is under the active test mode, the test control module further transmits a auxiliary measurement result to the self-test unit.

14. The functional test system of claim 8, wherein the interface module further comprises an universal asynchronous receiver transmitter (UART) interface, an I²C interface, an universal serial bus (USB) interface, a Bluetooth interface or a combination of the above, and the test control module and the under-test module communicate with each other through the UART interface, the I²C interface, the USB interface, the Bluetooth interface or the combination of the above.

15. A functional test method used in a fixture comprising:
communicating with a self-test unit of an under-test module by a test control module of the fixture through an interface module of the fixture to control the under-test module to activate a test flow;
determining whether the under-test module is under a passive test mode or an active test mode;
transmitting at least one test command by the test control module to the self-test unit to perform tests when the under-test module is under the passive test mode;
receiving a control command and/or a test result by the test control module passively from the self-test unit and further performing the tests on the under-test module by the test control module by controlling the interface module according to the control command and/or analyze the test result when the under-test module is under the active test mode.

16. The functional test method of claim 15, wherein the under-test module is under the passive test mode when the test flow is initialized.

17. The functional test method of claim 15, wherein when the under-test module is under the passive test mode, the functional test method further comprises transmitting an active test mode switching command by test control module such that the under-test module switches to the active test mode.

18. The functional test method of claim 15, wherein when the under-test module is under the passive test mode, the self-test unit activates at least one under-test unit of the under-test module according to the test command and when the under-test module is under the active test mode, the self-test unit activates the under-test unit directly.

19. The functional test method of claim 15, wherein when the under-test module is under the active test mode, the functional test method further comprises determining the under-test module is switched to the passive test mode when the test control module receives a passive test mode switching command from the self-test unit.

20. The functional test method of claim 15, further comprising transmits a auxiliary measurement result to the self-test unit after the test control module controls the auxiliary test units to perform test according to the test command when the under-test module is under the active test mode.
